(19) United States
(12) Patent Application Publication
(10) Pub. No.: US 2009/0177943 A1
(43) Pub. Date: Jul. 9, 2009

(54) ERROR CORRECTION CODING USING SOFT INFORMATION AND INTERLEAVING

(75) Inventors: GREGORY L. SILVUS, BOULDER, CO (US); ISMAIL DEMIRKAN, SUPERIOR, CO (US)

Correspondence Address: GARLICK HARRISON & MARKISON, P.O. BOX 160727, AUSTIN, TX, 78716-0727, US

(73) Assignee: BROADCOM CORPORATION, IRVINE, CA (US)

(21) Appl. No.: 12/114,066

(22) Filed: May 2, 2008

Related U.S. Application Data
(60) Provisional application No. 61/019,955, filed on Jan. 9, 2008.

(51) Int. Cl. H03M 13/29; G06F 11/10; H03M 13/05

(52) U.S. Cl. 714/755; 714/752; 714/E11.032

(57) ABSTRACT

Error correction coding using soft information and interleaving. A symbol interleaved ECC signal (which can be a symbol interleaved multi-level ECC signal) initially undergoes detection (e.g., such as using SOVA detection) to generate soft information. A decoder uses the soft information to generate estimates of at least one symbol (or at least one bit) of the symbol interleaved multi-level ECC signal. Initially, each of the interleaves of the symbol interleaved multi-level ECC signal undergo decoding to determine whether or not any of the interleaves has correctable errors. If not, then a receiving device can request re-transmission of the symbol interleaved multi-level ECC signal from a transmitting device (or a re-read from media of a hard disk drive (HDD)). Interleaves having uncorrectable errors are associated with interleaves having correctable errors. Uncorrectable errors can be corrected via the use of erasure pointers or bit-flipping, among other means.

### CROSS REFERENCE TO RELATED PATENTS/PATENT APPLICATIONS

### Provisional Priority Claims

The present U.S. Utility Patent Application claims priority pursuant to 35 U.S.C. §119(e) to the following U.S. Provisional Patent Application which is hereby incorporated herein by reference in its entirety and made part of the present U.S. Utility Patent Application for all purposes:

1. U.S. Provisional Application Serial No. 61/019,955, entitled “Soft error correction code (ECC) through interleaving,” (Attorney Docket No. BP6733), filed 01-09-2008, pending.

### BACKGROUND OF THE INVENTION

1. Technical Field of the Invention

The invention relates generally to error correction decoding of signals; and, more particularly, it relates to leveraging interleaving and soft information to assist in decoding of such signals.

2. Description of Related Art

Data communication systems have been under continual development for many years. One such type of communication system that has been of significant interest lately is a communication system that employs error correction coding (ECC), the signals of which are sometimes decoded using an iterative process. Communication systems with ECC are often able to achieve lower error rates (ERs) than uncoded systems for a given signal-to-noise ratio (SNR).

A continual and primary directive in this area of development has been to try continually to lower the SNR required to achieve a given bit error rate (BER) (or block error rate (BLER)) within a communication system.

As is known, many varieties of data storage devices (e.g. hard disk drives (HDDs)), such as magnetic disk drives are used to provide data storage for a host device, either directly, or through a network such as a storage area network (SAN) or network attached storage (NAS). Such a memory storage system (e.g., a HDD) can itself be viewed as a communication system in which information is encoded and provided via a communication channel to a storage medium; the reverse direction of communication is also performed in a HDD in which data is read from the medium and passed through the communication channel (e.g., sometimes referred to as a read channel in the HDD context) at which point it is decoded to makes estimates of the information that is read.

Typical host devices include stand alone computer systems such as a desktop or a laptop computer, enterprise storage devices such as servers, storage arrays such as a redundant array of independent disks (RAID) arrays, storage routers, storage switches and storage directors, and other consumer devices such as video game systems and digital video recorders. These devices provide high storage capacity in a cost effective manner.

Some communication systems, including HDDs, employ error detecting and/or correcting codes to deal with errors that may be incurred within signals that are transmitted within such a communication system. In the HDD context, such undesirable errors can be incurred during the write and/or read processes to and from the storage media of the HDD. However, generally speaking, ECC can also be applied to virtually communication system (e.g., one type of which is an HDD).

### BRIEF SUMMARY OF THE INVENTION

The present invention is directed to apparatus and methods of operation that are further described in the following Brief Description of the Several Views of the Drawings, the Detailed Description of the Invention, and the claims. Other features and advantages of the present invention will become apparent from the following detailed description of the invention made with reference to the accompanying drawings.

### BRIEF DESCRIPTION OF THE SEVERAL VIEWS OF THE DRAWINGS

FIG. 1 illustrates an embodiment of a disk drive unit.

FIG. 2 illustrates an embodiment of an apparatus that includes a disk controller.

FIG. 3A illustrates an embodiment of a handheld audio unit.

FIG. 3B illustrates an embodiment of a computer.

FIG. 3C illustrates an embodiment of a wireless communication device.

FIG. 3D illustrates an embodiment of a personal digital assistant (PDA).

FIG. 3E illustrates an embodiment of a laptop computer.

FIG. 4 illustrates an embodiment of a communication system.

FIG. 5 illustrates an embodiment of an apparatus that is operable to decode a symbol-interleaved multi-level error correction coding (ECC) signal in accordance with encoding and decoding of signals within and between various communication devices.

FIG. 6 illustrates an alternative embodiment of an apparatus that is operable to decode a symbol-interleaved multi-level ECC signal in accordance with encoding and decoding of signals within and between various communication devices.

FIG. 7 illustrates an embodiment of an apparatus implemented to perform decoding of a signal.

FIG. 8 illustrates an embodiment of a relationship between a standard multi-level ECC signal and a symbol-interleaved multi-level ECC signal.

FIG. 9 illustrates an embodiment of decoding of a symbol-interleaved multi-level ECC signal.

FIG. 10, FIG. 11, and FIG. 12 illustrates embodiments of processing the various interleaves of a symbol-interleaved multi-level ECC signal.

FIG. 13 and FIG. 14 illustrate embodiments of performance comparisons of various means to decode a symbol-interleaved multi-level ECC signal.

FIG. 15 illustrates an embodiment of a method for correcting an error within a signal.

### DETAILED DESCRIPTION OF THE INVENTION

A novel means is presented herein in which the nature of interleaving employed when generating an error correction coding (ECC) signal is capitalized upon when decoding that ECC signal. More particularly, the when decoding an ECC signal, the soft information generated/calculated therein is employed, and based on the interleaving of the ECC signal, more effective error correction can be performed than within prior art approaches.

The type of signal can be a symbol interleaved-ECC signal or multi-level ECC signal in some embodiments. Herein, it is noted that any reference to operating on a symbol interleaved-ECC signal can also be applied to a multi-level ECC signal, and vice versa. Moreover, it is noted that the novel means presented herein can also be equally applied to embodiments employing signal that do not include multi-level ECC signals (e.g., can be applied to non-multi-level ECC signals as well without departing from the scope and spirit of the invention). Generally speaking, the novel means presented herein can be equally applied to any ECC signals (e.g., those not multi-level in nature) and/or multi-level ECC signals.

A symbol interleaved multi-level ECC signal initially undergoes detection (e.g., such as using the Soft Output Viterbi Algorithm (SOVA)) to generate soft information (e.g., log likelihood ratios (LLRs) or some other form of sift information as may be desired in a given embodiment). A subsequent decoder (e.g., a RS (Reed-Solomon) decoder, a LDPC (Low Density Parity Check) decoder, other type of decoder, etc.) then uses the soft information to generate estimates of at least one symbol (or at least one bit) of the symbol interleaved-ECC signal or multi-level ECC signal. As is known in the art, various different decoders employ different processes and means to perform decoding (e.g., RS decoding on a symbol basis, LDPC decoding on a bit basis, and so on). Regardless of which type of ECC is employed, the means presented herein can capitalize on using soft information and interleaving employed therein.

Initially, each of the interleaves of the symbol interleaved multi-level ECC signal undergo decoding to correct any errors contained therein. However, there may be instances where one or more errors within one of more of the interleaves are uncorrectable. In this situation, there will at least be knowledge of where those one or more uncorrectable errors is/are located. If none of the interleaves has at least one error that can be corrected during decoding, then a receiving device can request re-transmission of the signal (e.g., a symbol interleaved multi-level ECC signal) from a transmitting device (or request a re-read from media of a hard disk drive (HDD)). Interleaves having uncorrectable errors are correlated with interleaves having uncorrectable errors by identifying the locations of errors in the correctable interleaves and associating their soft information with nearby soft information in uncorrectable interleaves.

For example, when there is at least one interleave including errors that can be corrected, then that particular interleave can be employed to assist in the decoding/correction of errors in interleaves including uncorrectable errors. For example, these two interleaves (one having correctable errors and one having uncorrectable errors) are then correlated so that the uncorrectable errors within the one interleave can be corrected via the use of erasure pointers or bit-flipping, among other means.

It is noted that if error correction within all of the interleaves, during the original decoding attempt, does in fact succeed, then that initial decoding can be employed without performing subsequent processing that capitalizes on the interleaved nature of the symbol interleaved multi-level ECC signal.

The decoding can continue by processing additional and successive interleaves once a first interleave having correctable errors has been identified and those corrected errors of the first interleave are used to correct a second interleave having an uncorrectable error.

Generally speaking, reliability information output from a soft-output detector (e.g., a SOVA detector in some embodiments) is used to improve the performance of interleaved error correction codes. By leveraging the corrected positions in interleaves that are successfully decoded (e.g., during an initial decoding attempt), the soft information values are examined at the boundaries of the interleaving to locate “erasure pointers” that may subsequently be used to extend the correction power in interleaves that are not originally characterized as having correctable errors.

It is noted that reliability information such as that generated by a soft detector (e.g., a SOVA detector) is generally about 50% “reliable”. That is to say, if the soft information value indicates a bit is bad, there is about a 50/50 chance that the bit really is bad.

Some previous approaches have operated by making lists of potential errors and checked each and every item in the list. Such a previous approach is inherently time-consuming and inefficient. In some application contexts (e.g., those employing an HDD with a channel coupled to a storage medium), the error events in such channels are oftentimes correlated. In other words, these error events include correlated strings of more than one bit error at a time. If these error events cross an ECC symbol boundary (such as when a RS code is employed, which operates on a symbol-level-basis) and that boundary is spread across multiple interleaves of the symbol interleaved multi-level ECC signal, then a correctable interleave can be used to identify which unreliable information is actually incorrect. With this novel approach, there is no need to build a list (and check that list) because it is actually known, with a much greater certainty, when the bit is really in error.

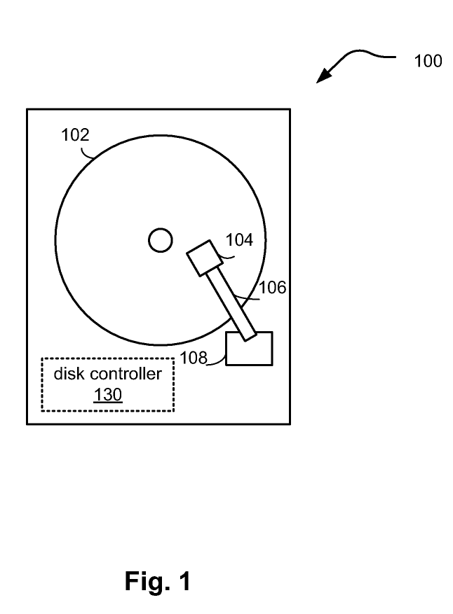

FIG. 1 illustrates an embodiment of a disk drive unit 100. In particular, disk drive unit 100 includes a disk 102 that is rotated by a servo motor (not specifically shown) at a velocity such as 3600 revolutions per minute (RPM), 4200 RPM, 4800 RPM, 5,400 RPM, 7,200 RPM, 10,000 RPM, 15,000 RPM; however, other velocities including greater or lesser velocities may likewise be used, depending on the particular application and implementation in a host device. In one possible embodiment, disk 102 can be a magnetic disk that stores information as magnetic field changes on some type of magnetic medium. The medium can be a rigid or non-rigid, removable or non-removable, that consists of or is coated with magnetic material.

Disk drive unit 100 further includes one or more read/write heads 104 that are coupled to arm 106 that is moved by actuator 108 over the surface of the disk 102 either by translation, rotation or both. A disk controller 130 is included for controlling the read and write operations to and from the drive, for controlling the speed of the servo motor and the motion of actuator 108, and for providing an interface to and from the host device.

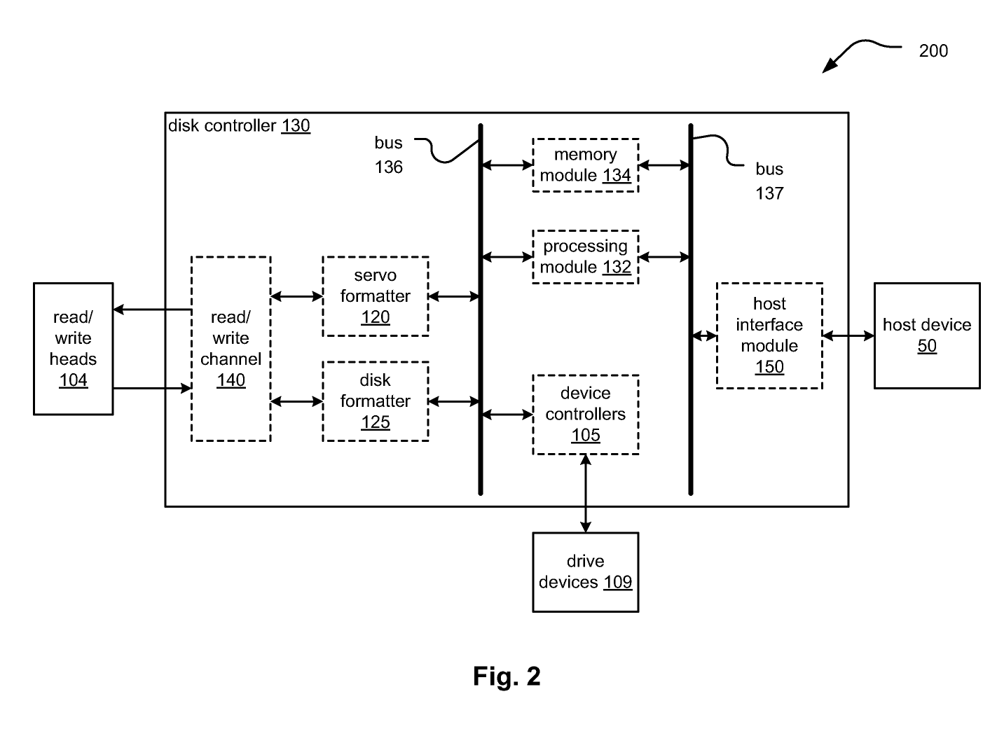

FIG. 2 illustrates an embodiment of an apparatus 200 that includes a disk controller 130. In particular, disk controller 130 includes a read/write channel 140 for reading and writing data to and from disk 102 through read/write heads 104. Disk formatter 125 is included for controlling the formatting of data and provides clock signals and other timing signals that control the flow of the data written to, and data read from disk 102. Servo formatter 120 provides clock signals and other timing signals based on servo control data read from disk 102. Device controllers 105 control the operation of drive devices 109 such as actuator 108 and the servo motor, etc. Host interface 150 receives read and write commands from host device 50 and transmits data read from disk 102 along with other control information in accordance with a host interface protocol. In one embodiment, the host interface protocol can include, SCSI, SATA, enhanced integrated drive electronics (EIDE), or any number of other host interface protocols, either open or proprietary that can be used for this purpose.

Disk controller 130 further includes a processing module 132 and memory module 134. Processing module 132 can be implemented using one or more microprocessors, micro-controllers, digital signal processors, microcomputers, central processing units, field programmable gate arrays, programmable logic devices, state machines, logic circuits, analog circuits, digital circuits, and/or any devices that manipulates signal (analog and/or digital) based on operational instructions that are stored in memory module 134. When processing module 132 is implemented with two or more devices, each device can perform the same steps, processes or functions in order to provide fault tolerance or redundancy. Alternatively, the function, steps and processes performed by processing module 132 can be split between different devices to provide greater computational speed and/or efficiency.

Memory module 134 may be a single memory device or a plurality of memory devices. Such a memory device may be a read-only memory, random access memory, volatile memory, non-volatile memory, static random access memory (SRAM), dynamic random access memory (DRAM), flash memory, cache memory, and/or any device that stores digital information. Note that when the processing module 132 implements one or more of its functions via a state machine, analog circuitry, digital circuitry, and/or logic circuitry, the memory module 134 storing the corresponding operational instructions may be embedded within, or external to, the circuitry comprising the state machine, analog circuitry, digital circuitry, and/or logic circuitry. Further note that, the memory module 134 stores, and the processing module 132 executes, operational instructions that can correspond to one or more of the steps or a process, method and/or function illustrated herein.

Disk controller 130 includes a plurality of modules, in particular, device controllers 105, processing module 132, memory module 134, read/write channel 140, disk formatter 125, and servo formatter 120 that are interconnected via bus 136 and bus 137. The host interface 150 can be connected to only the bus 137 and communicates with the host device 50. Each of these modules can be implemented in hardware, firmware, software or a combination thereof, in accordance with the broad scope of the present invention. While a particular bus architecture is shown in FIG. 2 with buses 136 and 137, alternative bus architectures that include either a single bus configuration or additional data buses, further connectivity, such as direct connectivity between the various modules, are likewise possible to implement the features and functions included in various embodiments.

In one possible embodiment, one or more modules of disk controller 130 are implemented as part of a system on a chip (SoC) integrated circuit. In an embodiment, this SoC integrated circuit includes a digital portion that can include additional modules such as protocol converters, linear block code encoding and decoding modules, etc., and an analog portion that includes device controllers 105 and optionally additional modules, such as a power supply, etc. In a further embodiment, the various functions and features of disk controller 130 are implemented in a plurality of integrated circuit devices that communicate and combine to perform the functionality of disk controller 130.

When the drive unit 100 is manufactured, disk formatter 125 writes a plurality of servo wedges along with a corresponding plurality of servo address marks at equal radial distance along the disk 102. The servo address marks are used by the timing generator for triggering the “start time” for various events employed when accessing the media of the disk 102 through read/write heads 104.

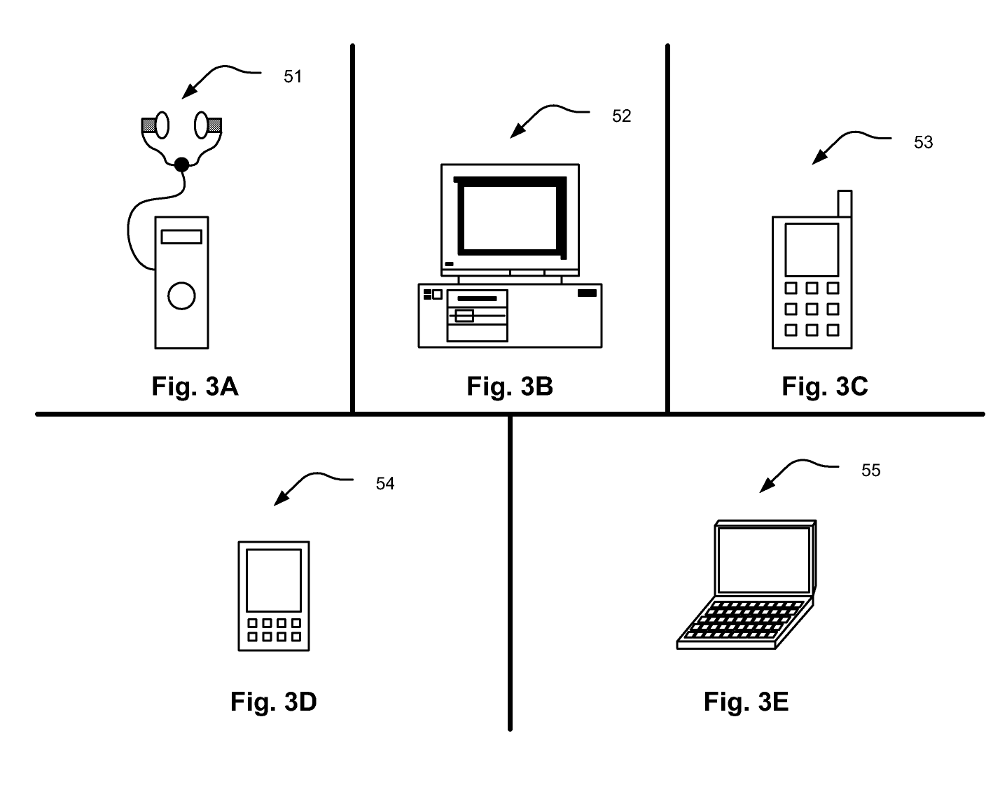

FIG. 3A illustrates an embodiment of a handheld audio unit 51. In particular, disk drive unit 100 can be implemented in the handheld audio unit 51. In one possible embodiment, the disk drive unit 100 can include a small form factor magnetic hard disk whose disk 102 has a diameter 1.8″ or smaller that is incorporated into or otherwise used by handheld audio unit 51 to provide general storage or storage of audio content such as motion picture expert group (MPEG) audio layer 3 (MP3) files or Windows Media Architecture (WMA) files, video content such as MPEG4 files for playback to a user, and/or any other type of information that may be stored in a digital format.

FIG. 3B illustrates an embodiment of a computer 52. In particular, disk drive unit 100 can be implemented in the computer 52. In one possible embodiment, disk drive unit 100 can include a small form factor magnetic hard disk whose disk 102 has a diameter 1.8″ or smaller, a 2.5″ or 3.5″ drive or larger for applications such as enterprise storage applications. Disk drive 100 is incorporated into or otherwise used by computer 52 to provide general purpose storage for any type of information in digital format. Computer 52 can be a desktop computer, or an enterprise storage devices such a server, of a host computer that is attached to a storage array such as a redundant array of independent disks (RAID) array, storage router, edge router, storage switch and/or storage director.

FIG. 3C illustrates an embodiment of a wireless communication device 53. In particular, disk drive unit 100 can be implemented in the wireless communication device 53. In one possible embodiment, disk drive unit 100 can include a small form factor magnetic hard disk whose disk 102 has a diameter 1.8″ or smaller that is incorporated into or otherwise used by wireless communication device 53 to provide general storage or storage of audio content such as motion picture expert group (MPEG) audio layer 3 (MP3) files or Windows Media Architecture (WMA) files, video content such as MPEG4 files, JPEG (joint photographic expert group) files, bitmap files and files stored in other graphics formats that may be captured by an integrated camera or downloaded to the wireless communication device 53, emails, webpage information and other information downloaded from the Internet, address book information, and/or any other type of information that may be stored in a digital format.

In a possible embodiment, wireless communication device 53 is capable of communicating via a wireless telephone network such as a cellular, personal communications service (PCS), general packet radio service (GPRS), global system for mobile communications (GSM), and integrated digital enhanced network (iDEN) or other wireless communications network capable of sending and receiving telephone calls. Further, wireless communication device 53 is capable of communicating via the Internet to access email, download content, access websites, and provide steaming audio and/or video programming. In this fashion, wireless communication device 53 can place and receive telephone calls, text messages such as emails, short message service (SMS) messages, pages and other data messages that can include attachments such as documents, audio files, video files, images and other graphics.

FIG. 3D illustrates an embodiment of a personal digital assistant (PDA) 54. In particular, disk drive unit 100 can be implemented in the personal digital assistant (PDA) 54. In one possible embodiment, disk drive unit 100 can include a small form factor magnetic hard disk whose disk 102 has a diameter 1.8″ or smaller that is incorporated into or otherwise used by personal digital assistant 54 to provide general storage or storage of audio content such as motion picture expert group (MPEG) audio layer 3 (MP3) files or Windows Media Architecture (WMA) files, video content such as MPEG4 files, JPEG (joint photographic expert group) files, bitmap files and files stored in other graphics formats, emails, webpage information and other information downloaded from the Internet, address book information, and/or any other type of information that may be stored in a digital format.

FIG. 3E illustrates an embodiment of a laptop computer 55. In particular, disk drive unit 100 can be implemented in the laptop computer 55. In one possible embodiment, disk drive unit 100 can include a small form factor magnetic hard disk whose disk 102 has a diameter 1.8″ or smaller, or a 2.5″ drive. Disk drive 100 is incorporated into or otherwise used by laptop computer 52 to provide general purpose storage for any type of information in digital format.

The goal of digital communications systems is to transmit digital data from one location, or subsystem, to another either error free or with an acceptably low error rate. As shown in FIG. 1, data may be transmitted over a variety of communications channels in a wide variety of communication systems: magnetic media, wired, wireless, fiber, copper, and other types of media as well.

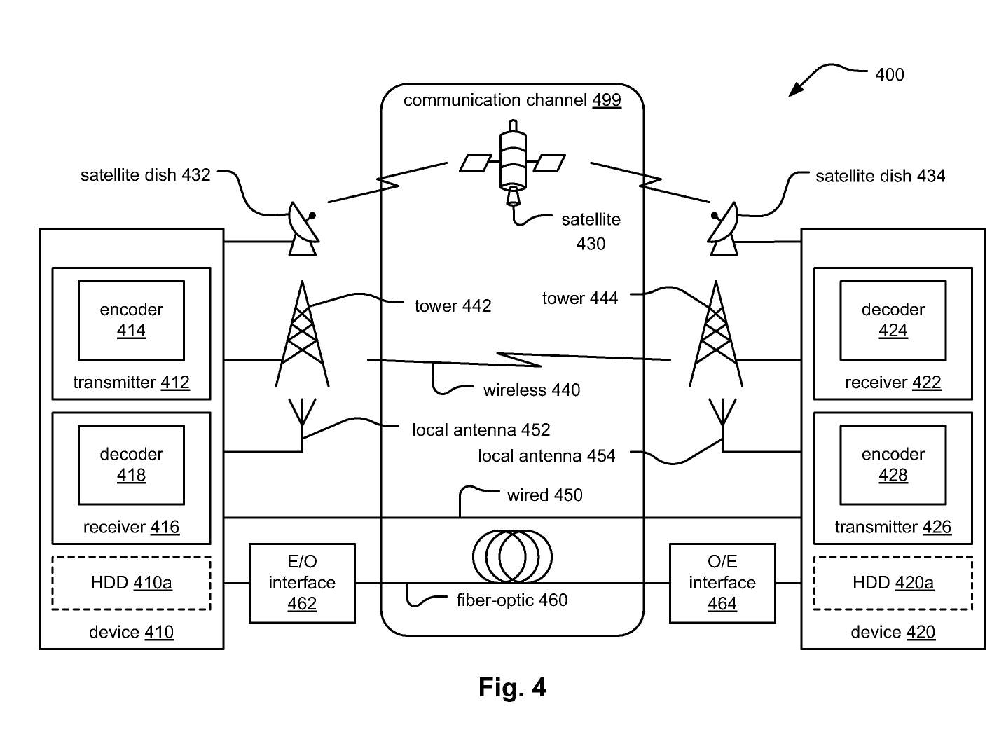

FIG. 4 is a diagram illustrating an embodiment of a communication system 400.

Referring to FIG. 4, this embodiment of a communication system 400 is a communication channel 499 that communicatively couples a communication device 410 (including a transmitter 412 having an encoder 414 and including a receiver 416 having a decoder 418) situated at one end of the communication channel 499 to another communication device 420 (including a transmitter 426 having an encoder 428 and including a receiver 422 having a decoder 424) at the other end of the communication channel 499. In some embodiments, either of the communication devices 410 and 420 may only include a transmitter or a receiver. There are several different types of media by which the communication channel 499 may be implemented (e.g., a satellite communication channel 430 using satellite dishes 432 and 434, a wireless communication channel 440 using towers 442 and 444 and/or local antennae 452 and 454, a wired communication channel 450, and/or a fiber-optic communication channel 460 using electrical to optical (E/O) interface 462 and optical to electrical (O/E) interface 464). In addition, more than one type of media may be implemented and interfaced together thereby forming the communication channel 499.

Either one of both of the communication device 410 and the communication device 420 can include a hard disk drive (HDD) (or be coupled to a HDD). For example, the communication device 410 can include a HDD 410a, and the communication device 420 can include a HDD 420a.

The signals employed within this embodiment of a communication system 400 can be Reed-Solomon (RS) coded signals, LDPC (Low Density Parity Check) coded signal, turbo coded signals, turbo trellis coded modulation (TTCM), or coded signal generated using some other error correction coding (ECC).

In addition, these signals can undergo processing to generate a symbol interleaved multi-level ECC signal that can be transferred between the communication device 410 and the communication device 420 (or vice versa) or transferred to and from the HDD 410a within the communication device 410 or to and from the HDD 420a within the communication device 420.

Any of a very wide variety of applications that perform transferring of signals from one location to another (e.g., including from a first location to a HDD, or from the HDD to another location) can benefit from various aspects of the invention, including any of those types of communication devices and/or communication systems depicted in FIG. 4. Moreover, other types of devices and applications that perform decoding of such signals can also benefit from various aspects of the invention.

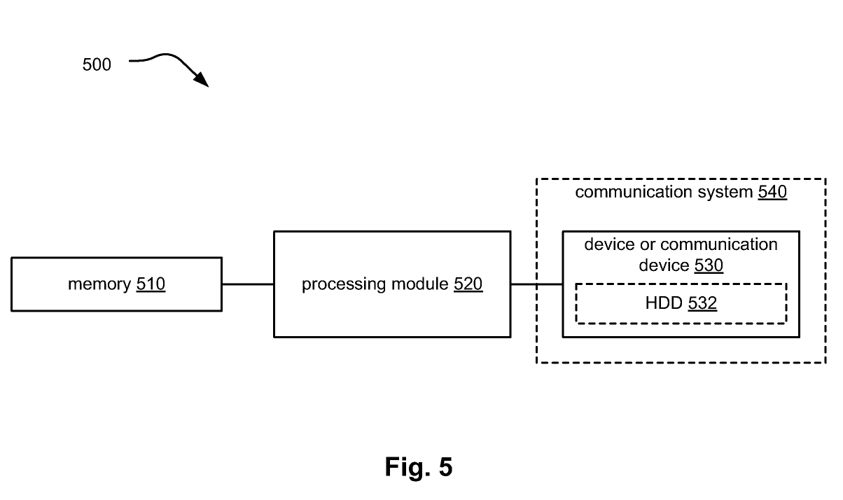

FIG. 5 illustrates an embodiment of an apparatus 500 that is operable to decode a symbol-interleaved multi-level error correction coding (ECC) signal in accordance with encoding and decoding of signals within and between various communication devices. The apparatus 500 includes a processing module 520, and a memory 510. The memory 510 is coupled to the processing module, and the memory 510 is operable to store operational instructions that enable the processing module 520 to perform a variety of functions. The processing module 520 is operable to perform the appropriate decoding of a symbol interleaved multi-level ECC signal using any of the approaches presented herein.

The processing module 520 can be implemented using a shared processing device, individual processing devices, or a plurality of processing devices. Such a processing device may be a microprocessor, micro-controller, digital signal processor, microcomputer, central processing unit, field programmable gate array, programmable logic device, state machine, logic circuitry, analog circuitry, digital circuitry, and/or any device that manipulates signals (analog and/or digital) based on operational instructions. The memory 510 may be a single memory device or a plurality of memory devices. Such a memory device may be a read-only memory, random access memory, volatile memory, non-volatile memory, static memory, dynamic memory, flash memory, and/or any device that stores digital information. Note that when the processing module 520 implements one or more of its functions via a state machine, analog circuitry, digital circuitry, and/or logic circuitry, the memory storing the corresponding operational instructions is embedded with the circuitry comprising the state machine, analog circuitry, digital circuitry, and/or logic circuitry.

If desired in some embodiments, the means of performing decoding of a symbol interleaved multi-level ECC signal can be provided from the apparatus 500 to a communication system 540 that is operable to employ and perform such decoding. The means of performing decoding of a symbol interleaved multi-level ECC signal can also be provided from the apparatus 500 to any of a variety of devices or communication devices 530 implemented within the communication system 540 as well. The device or communication device 530 can include a HDD 532 in certain embodiments.

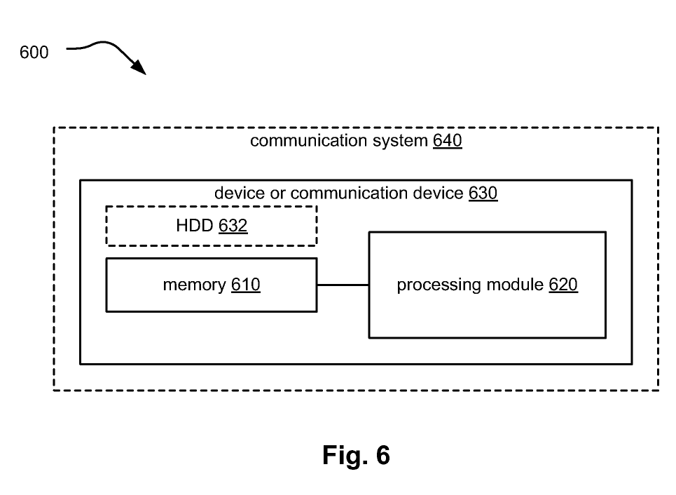

FIG. 6 illustrates an alternative embodiment of an apparatus 600 that is operable to decode a symbol-interleaved multi-level ECC signal in accordance with encoding and decoding of signals within and between various communication devices. The apparatus 600 includes a processing module 620, and a memory 610. The memory 610 is coupled to the processing module, and the memory 610 is operable to store operational instructions that enable the processing module 620 to perform a variety of functions. The processing module 620 (serviced by the memory 610) can be implemented as an apparatus capable to perform any of the functionality of any of the various modules and/or functional blocks described herein. For example, the processing module 620 (serviced by the memory 620) can be implemented as an apparatus capable to decode of a symbol interleaved multi-level ECC signal using any of the various embodiments described herein.

The processing module 620 can be implemented using a shared processing device, individual processing devices, or a plurality of processing devices. Such a processing device may be a microprocessor, micro-controller, digital signal processor, microcomputer, central processing unit, field programmable gate array, programmable logic device, state machine, logic circuitry, analog circuitry, digital circuitry, and/or any device that manipulates signals (analog and/or digital) based on operational instructions. The memory 610 may be a single memory device or a plurality of memory devices. Such a memory device may be a read-only memory, random access memory, volatile memory, non-volatile memory, static memory, dynamic memory, flash memory, and/or any device that stores digital information. Note that when the processing module 620 implements one or more of its functions via a state machine, analog circuitry, digital circuitry, and/or logic circuitry, the memory storing the corresponding operational instructions is embedded with the circuitry comprising the state machine, analog circuitry, digital circuitry, and/or logic circuitry.

If desired in some embodiments, the apparatus 600 can be any of a variety of devices, or any part or portion of any such device or communication device. The device or communication device 630 can include a HDD 632 in certain embodiments. Any such communication device that includes the apparatus 600 can be implemented within any of a variety of communication systems 640 as well. It is also noted that various embodiments of decoding of a symbol interleaved multi-level ECC signal as presented herein, and equivalents thereof, may be applied to many types of communication systems and/or communication devices.

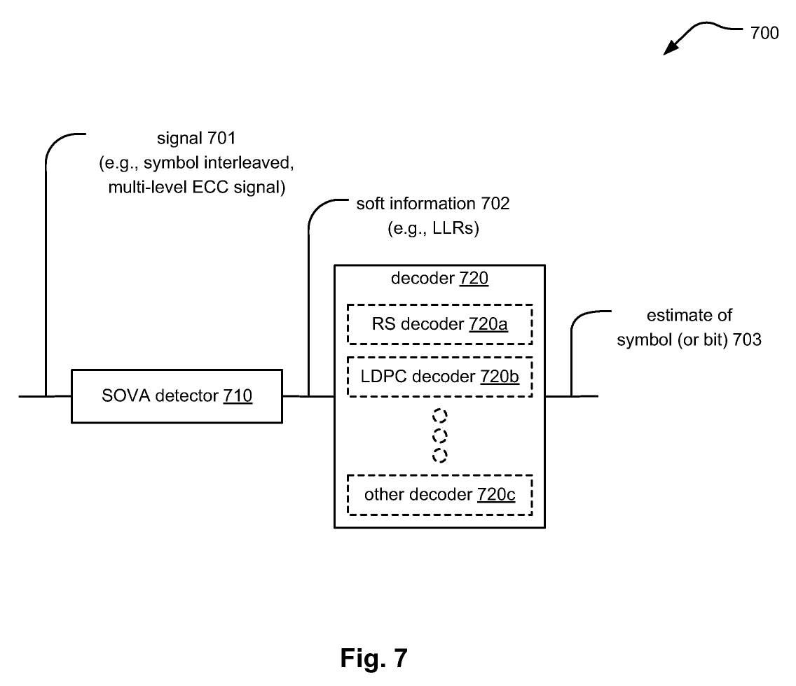

FIG. 7 illustrates an embodiment of an apparatus 700 implemented to perform decoding of a signal. A signal 701 (e.g., a symbol-interleaved multi-level ECC signal) is received by a Soft Output Viterbi Algorithm (SOVA) detector 710 that is implemented to perform detection of the bits within the signal 701 (e.g., detect all of the bits in the received sequence). This detection generates initial estimates of the values of each bit within the signal 701.

Soft information is then calculated based on the initial estimates generated during the detection performed by the SOVA detector 710. Soft information values 702 are then available corresponding to each of the bits of the signal. For example, each soft information value corresponds to one bit of the signal. The soft information values 702 can be calculated as log likelihood ratios (LLRs) or in another desired manner.

Thereafter, a decoder 720 is implemented to employ either the detected bit values (e.g., initial estimates) or the soft information values 702 for each (and every) bit and decodes the sequence to correct any errors included therein. The decoder 720 is implemented to make an estimate 703 of at least one symbol (or at least one bit) of the signal.

In some embodiments, the decoder 720 is a RS (Reed-Solomon) decoder (such as depicted by reference numeral 720a) implemented to process the soft information values 702 to make an estimate of at least one symbol of the signal. In an alternative embodiment in which the decoder 720 performs decoding on a bit-level basis (e.g., an LDPC (Low Density Parity Check) decoder as depicted by reference numeral 720b), then such an LDPC decoder can be implemented to process the soft information values 702 to make an estimate of at least one bit of the signal. Another form of decoding can alternatively be employed as depicted generally by the other decoder 720c. In even other applications, more than one type of decoder can be implemented therein so that various coded signals can be decoded by a single device.

Looking at one such embodiment that includes a RS decoder, such a RS decoder initially performs decoding on bits within each interleave of the symbol-interleaved multi-level ECC signal. If one or more interleave is correctable (but not all the interleaves are correctable), then the RS decoder can perform a few functions including identifying a first interleave of the symbol-interleaved multi-level ECC signal that has a correctable error. The RS decoder then identifies a second interleave of the symbol-interleaved multi-level ECC signal that has an uncorrectable error whose bit position is adjacent to a bit position within the first interleave that includes the correctable error. The very nature of the interleaving performed when generating the symbol-interleaved multi-level ECC signal can be exploited to correct for errors in those interleaves that are initially identified as being uncorrectable (e.g., having an error that wasn't able to be corrected). To perform actual ‘correction’ of the uncorrectable error of the second interleave, the one or more errors in that interleave can be identified (e.g., using one or more of the correctable interleaves), the one or more potential (probable) uncorrectable errors of the second interleave are modified in some way to remove or lessen their impact. For example, if an interleave has a number of errors that is beyond the error correcting capability of the decoder, then one or more of those errors in an effort to make the result correctable.

To finalize this correction of the uncorrectable error, such an RS decoder can perform one of at least two functions. The RS decoder can identify an erasure pointer to partner the correctable error of the first interleave and the uncorrectable error of the second interleave. Alternatively, the RS decoder can perform a bit flip of the uncorrectable error of the second interleave (the one having the error originally identified as being uncorrectable).

In one embodiment, when the initial decoding of each interleave of the plurality of interleaves of the symbol-interleaved multi-level ECC signal succeeds, the decoder 720 then employs the initially successful decoding to make an estimate of a symbol (or a bit) within the signal. Alternatively, when the initial decoding of each interleave of the plurality of interleaves of the symbol-interleaved multi-level ECC signal fails, the apparatus itself can request a re-transmission of the signal to the apparatus from a sending/transmitting device that originally sent the symbol-interleaved multi-level ECC signal. In a HDD application, the apparatus can perform/attempt another read of the symbol-interleaved multi-level ECC signal from the storage media of the HDD.

It is generally noted that the decoding, as described herein, uses the correctable (or corrected) interleaves of a symbol-interleaved multi-level ECC signal to find valid soft information therein. This soft information is then associated with other appropriate interleaves within the symbol-interleaved multi-level ECC signal so that errors within those correlated/associated interleaves may be deal with accordingly. The very nature of the SOVA detection processing provides a situation where all bits affected by an error event may typically be treated as having the same probability (e.g., the same LLR). Moreover, bits relatively close to one another and whose soft information has a similar value may generally be viewed as being part of a same error event.

It is noted, also, that depending on the type of ECC being employed, there should also be the appropriate association of the soft information on a symbol or bit basis. For example, RS decoding operates on a symbol-level basis, while LDPC decoding operates on a bit-level basis.

It is noted that this decoding employed herein can be extended to a wide variety of ECC codes. Once errors within one of the interleaves is corrected, that corrected interleave can then be employed to correct other of the interleaves that were initially deemed to be uncorrectable.

The SOVA detection ranks the reliability of each bit detected (e.g., generating both a soft estimate of the bit and a reliability of that decision). The detection processing generally makes mistakes in correlated events that may cause errors affecting more than one bit (e.g., bursty, spurious events that affect a localization in the bit stream). The nature of the interleaving is capitalized upon such that once the location of a correctable error is known, and based on the interleaving, then correlated locations as being associated with common error events can also be corrected. For example, the reliability of each bit in an error event is approximately the same, and once one bit is found in a particular error event, then the other affected bits are relatively easy to find.

In the HDD context, it is noted that uncorrectable sectors can occur when the Signal-to-Noise Ratio (SNR) of the system (e.g., read channel of the HDD) in which the signal being read is poor. This can result in relatively longer error events, and these relatively longer error events may be appropriately supposed to cross ECC boundaries. Considered from another perspective, in relatively lower SNR systems, the error events can be longer than in relatively higher SNR systems. Consequently, in such relatively lower SNR systems, longer error events are more likely to cross symbol boundaries because the symbols employed therein contain a finite number of bits.

Considering a RS decoding embodiment, the relatively longer error events may be appropriately supposed to cross RS ECC symbol boundaries. In addition, if t is large, then the chances that at least one of the error events that makes an interleave uncorrectable will cross a symbol boundary. Because the symbol boundaries are also interleave boundaries, uncorrectable and correctable interleaves will be adjacent, and it is therefore likely that some number of error events will cross (or be shared across) interleave boundaries. In the RS decoding context, the distance, Δ, of a RS code is defined by the sum of the number of parity symbols plus one. Also in the RS decoding context, t is the number of error(s) where a location is not known, and e is the number of error(s) where a location is known (e.g., erasures).

Therefore, the following relationship holds:

Δ−1=2·t+e

The soft information values (e.g., as provided by a SOVA detector) can provide reliability information which can then be employed to pin down a location of an error; however, this information is generally only approximately 50% accurate. Again, the nature of the interleaving is capitalized upon such that once the location of a correctable error is known within one interleave, and based on the interleaving, then correlated locations in corresponding interleaves (e.g., in a common error event) that also have errors can also be corrected.

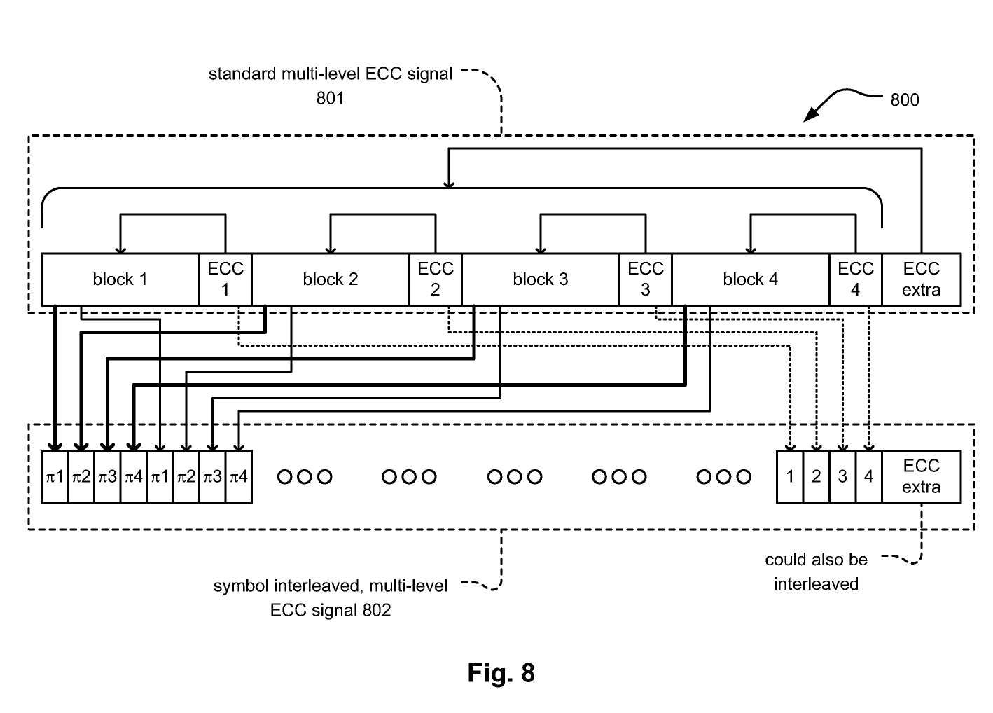

FIG. 8 illustrates an embodiment of a relationship 800 between a standard multi-level ECC signal 801 and a symbol-interleaved multi-level ECC signal 802. The standard multi-level ECC signal 801 includes a first information block (shown as block 1) followed by a corresponding first ECC block (shown as ECC 1), a second information block (shown as block 2) followed by a corresponding second ECC block (shown as ECC 2), and so on for a particular number of ECC blocks and corresponding ECC blocks (e.g., this embodiment shows 4 ECC blocks and 4 corresponding ECC blocks.

An extra ECC block (shown as ECC extra) that corresponds all of the information block and the ECC blocks is situated at the end of the standard multi-level ECC signal 801. It is noted here that the extra ECC block (shown as ECC extra) is in fact that multi-level part of each of the standard multi-level ECC signal 801 and the symbol-interleaved multi-level ECC signal 802. Without the extra ECC block (shown as ECC extra), neither the standard multi-level ECC signal 801 nor the symbol-interleaved multi-level ECC signal 802 would in fact be “multi-level”, and would alternatively be a standard ECC signal and a symbol-interleaved ECC signal, respectively. The novel means presented herein can be equally applied to all such types of ECC signals generated using some interleaving.

The symbol-interleaved multi-level ECC signal 802 is generated from the standard multi-level ECC signal 801 using selected symbols that are interleaved from each of the information blocks (4 information blocks in this particular embodiment) followed by selected symbols that are selectively interleaved from each of the ECC blocks (4 ECC blocks in this particular embodiment). In this embodiment, the extra ECC block is situated at the end of the symbol-interleaved multi-level ECC signal 802, though it is noted that symbols of the extra ECC block could also undergo interleaving as well.

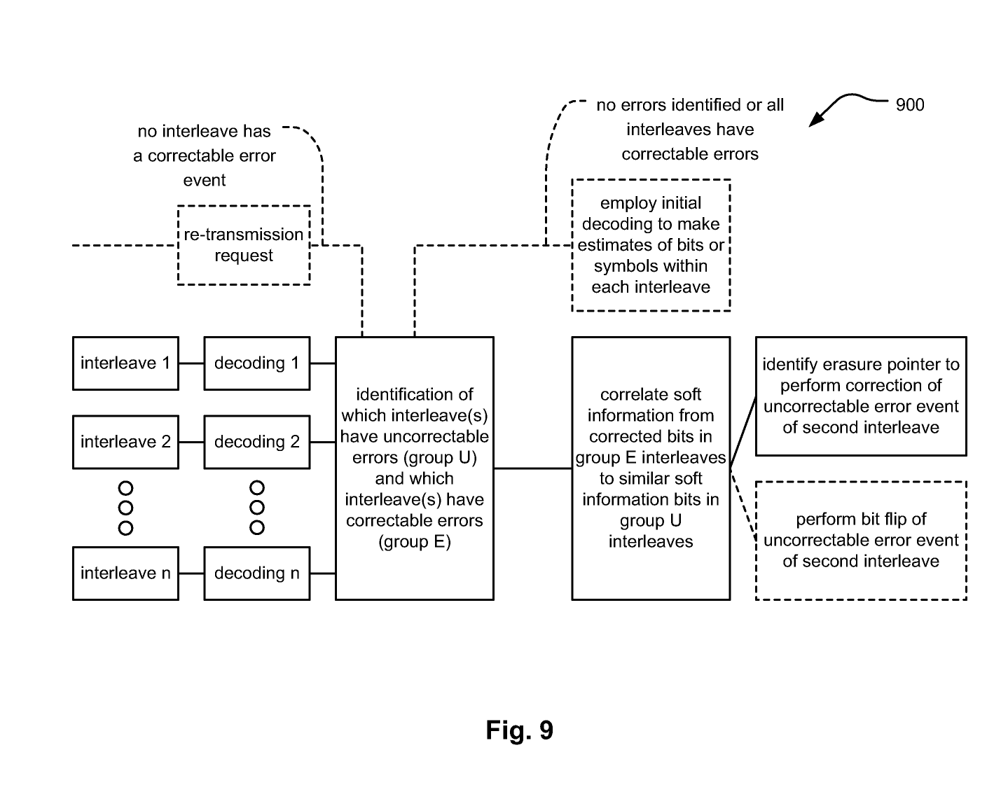

FIG. 9 illustrates an embodiment of decoding 900 of a symbol-interleaved multi-level ECC signal. The decoding 900 initially operates by performing standard error correction on each interleave of a symbol-interleaved multi-level ECC signal (the interleaves shown as interleave 1, interleave 2, . . . interleave n and the decoding performed on each interleave is shown by decoding 1, decoding 2, . . . decoding n).

Then, error correction decoding is performed. If the error correction decoding fails, then an interleave is uncorrectable and this provides identification of which interleaves, if any, have errors and particularly which of those interleaves with errors have uncorrectable errors. For example, this operation can be viewed as performing the identification of which interleave(s) have uncorrectable errors (group U) and which interleave(s) have correctable errors (group E). If none of the interleaves has a correctable error, then the a device that has received the symbol-interleaved multi-level ECC signal can request a re-transmission of the symbol-interleaved multi-level ECC signal to it. In an HDD context, if none of the interleaves has a correctable error, then the device that has attempted a read of the symbol-interleaved multi-level ECC signal from the storage media of the HDD, then the device can perform a re-read (or re-attempt the read) of the symbol-interleaved multi-level ECC signal from the storage media of the HDD.

It is also noted that if all of the interleaves with errors have correctable errors or if no errors are identified, then no further processing is required. That is to say, the results of the initial decoding (e.g., that has no identified errors) can be employed to make estimates of bits or symbols within each interleave of the symbol-interleaved multi-level ECC signal.

However, if at least one of the interleaves has a correctable error and at least one of the interleaves has an uncorrectable error, then the decoding 900 can operate to identify correlated first and second interleaves such that the first interleave has the correctable error and the second interleave has the uncorrectable error. The decoding 900 operates to correlate soft information from corrected bits in group E interleaves to similar soft information bits in group U interleaves.

The decoding 900 then corrects the correctable error in the first interleave, and based thereupon, the decoding 900 can then perform one of a number of different options to correct the uncorrectable error in the second interleave. The decoding 900 can identify an erasure pointer to perform correction of the uncorrectable error in the second interleave. Alternatively, the decoding 900 can perform a bit flip of the uncorrectable error in the second interleave.

Generally, when the multi-level correction of the symbol-interleaved multi-level ECC signal fails, the decoding 900 operates to locate the bit errors in at least one interleave having correctable errors. These bit positions are then compared with the SOVA-generated soft information. Error events within this interleave that cross into interleaves having uncorrectable errors are then identified. Then, to perform the correction of the uncorrectable errors, the decoding 900 can employ erasure pointers and/or bit flips.

As errors within more interleaves are corrected, those now-corrected bits can be employed to correct errors in other interleaves that were originally characterized as having uncorrectable errors. This can be viewed as being an iterative processing in which a first interleave having correctable errors is employed to correct errors within a second interleave having uncorrectable errors. Then, either one or both of the first interleave and the second interleave (whose originally uncorrectable errors have now been corrected) are employed to correct errors within a third interleave having uncorrectable errors, and so on.

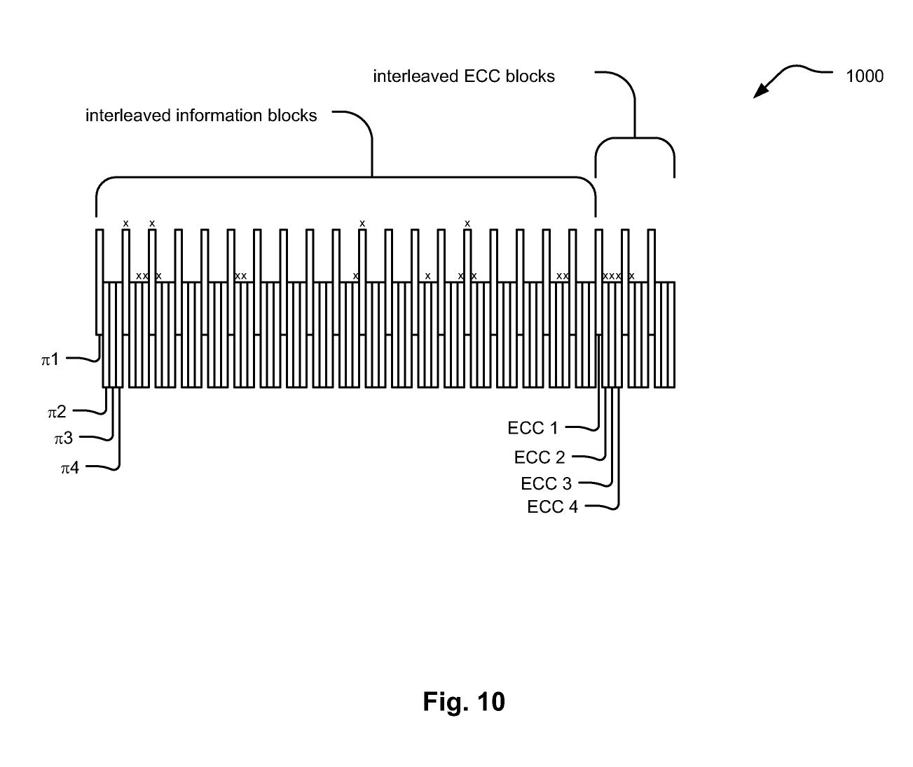

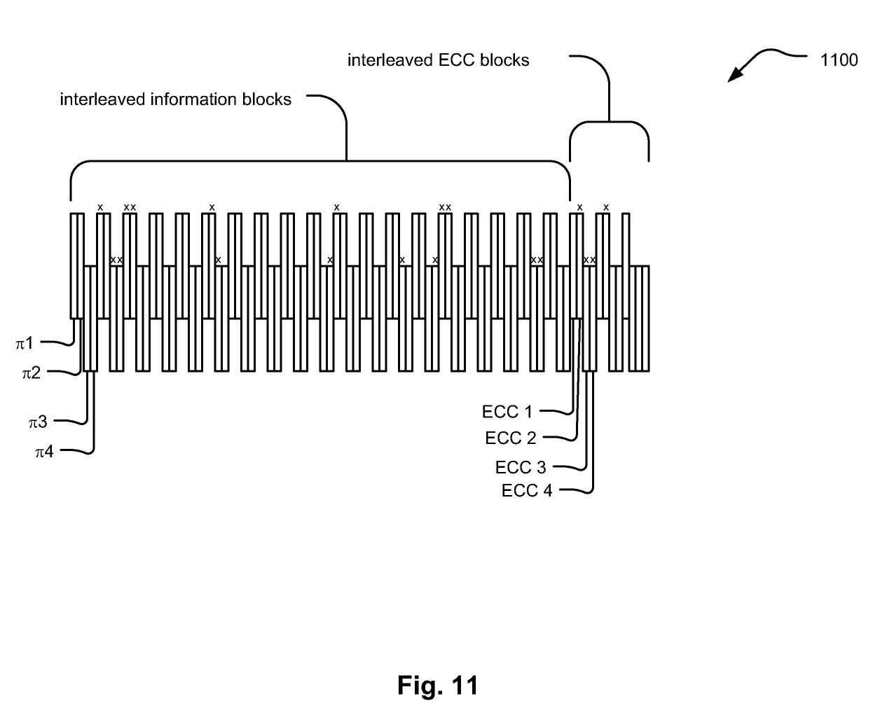

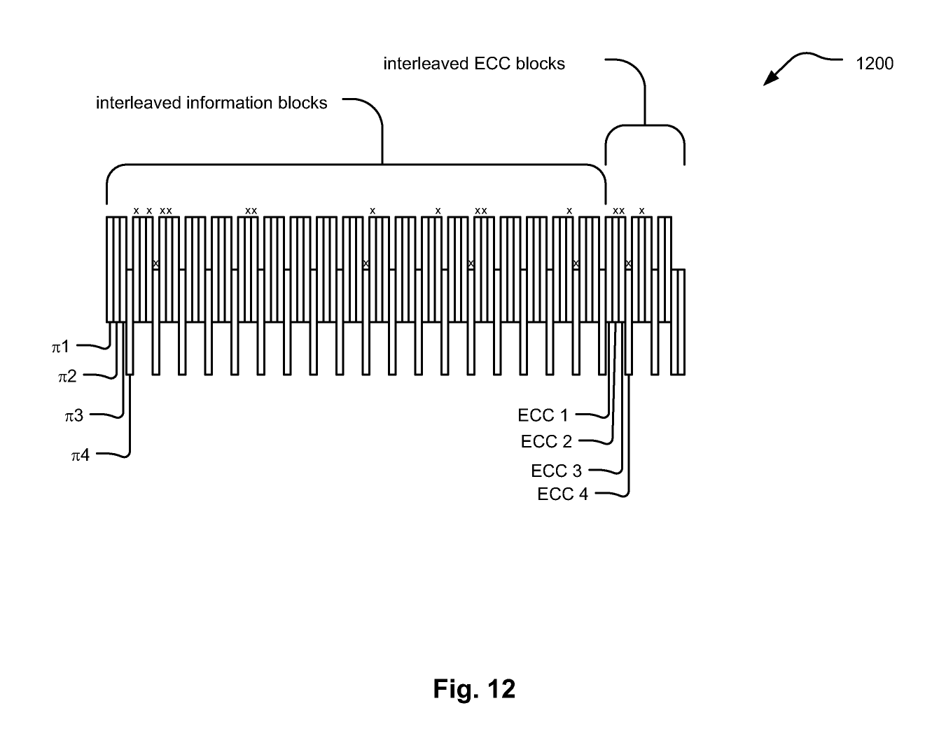

FIG. 10, FIG. 11, and FIG. 12 illustrates embodiments of processing the various interleaves of a symbol-interleaved multi-level ECC signal.

As also stated elsewhere, the novel means presented herein can be applied to systems employing any number of interleaves greater than or equal to 2. Some of the particular embodiments described herein employ a certain number of interleaves (e.g., 4 interleaves in some of the sub sequent embodiments), but the reader is reminded of the broad applicability of the means presented herein to other number of interleaves as well.

Referring to FIG. 10, four separate interleaves from four separate information blocks (shown as π1, π2, π3, and π4) of a symbol-interleaved multi-level ECC signal and four separate interleaves from four separate ECC blocks (shown as ECC1, ECC2, ECC3, and ECC4) are shown in their interleaved positions next to one another. It is noted that the patterns of interleaving (π1, π2, π3, and π4 followed by another π1, π2, π3, and π4 followed by another π1, π2, π3, and π4, etc.) and (ECC1, ECC2, ECC3, and ECC4 followed by another ECC1, ECC2, ECC3, and ECC4 followed by another ECC1, ECC2, ECC3, and ECC4, etc.)

Considering an embodiment in which this symbol-interleaved multi-level ECC signal has been generated using RS encoding, and the RS code has t=4 (i.e., meaning the code can correct 4 or fewer errors), then it can be seen in this exemplary embodiment that the entire signal only has one interleave (i.e., the first interleave (π1)) that has correctable errors.

Also considering the diagram, if it is supposed that the 2^{nd} and 4^{th} symbols of the first information bit interleave (π1) having an error (indicated by “x”) have one or two bits of a +−+ error event straddling the second information bit interleave (π2), then based on the correlation of the bits in these two interleaves (i.e., π1 and π2). The errors in the second information bit interleave (π2) are now correctable (this embodiment showing 2 erasures and 3 corrections). This is also based on this particular embodiment in which it is supposed that the fourth ECC interleave (ECC 4) has only one straddle with the first information bit interleave (π1) at the 4^{th} position.

Alternatively, this is based on the hope that, in processing the soft information, the adjacent errors for the 2^{nd} and 4^{th} errors of the first information bit interleave (π1) are related to the second information bit interleave (π2). This is based on an assumption of the particular type of error event, in that, adjacent errors share ‘some’ error event that crosses an interleave boundary.

Referring to FIG. 11, we initially start on the basis that the first information bit interleave (π1) is in fact correctable. One at a time, each of the bit errors within the first information bit interleave (π1) are considered, and soft information in symbols adjacent to the corrected errors is considered to determine whether it closely matches the soft information of the corrected bits in the first information bit interleave (π1). If the soft information does match, then it may be assumed (in one embodiment) that those affected bits are part of a common error event (e.g., and therefore related to one another). Using the pattern of similar soft information values, some means (e.g., bit-flip, erasure, or other means) may then be employed to change or point to symbols that may be incorrect in other interleaves (e.g., the second information bit interleave (π2) and/or others) in an effort to correct them. It is noted that, at this point, it is unsure whether these symbols in the uncorrectable interleaves are in fact in error (i.e., because they are uncorrectable).

In this depicted embodiment, it was possible to remove 2 errors (i.e., near the first information bit interleave (π1), symbols 2 and 4) from the second information bit interleave (π2).

Now, the errors within the second information bit interleave (π2) have now been corrected based on their correlation with correctable errors within the originally correctable first information bit interleave (π1), so now there are two information bit interleaves (π1 and π2) whose errors included therein are in fact correctable (or have been corrected). Continuing to consider this diagram, if it is supposed that the 2^{nd} and 4^{th} symbol portions of the second information bit interleave (π2) having an error (indicated by “x”) straddle the third information bit interleave (π3), then the third information bit interleave (π3) is now correctable.

This process can be repeated using corrected bits from the first information bit interleave (π1) and the second information bit interleave (π2) to try to correct either the third information bit interleave (π3) or the fourth information bit interleave (π4).

Referring to FIG. 12, it can be seen that some errors form the third information bit interleave (π3) are able to be removed, and now the remaining errors within third information bit interleave (π3) can be corrected.

That is to say, some of the errors within the third information bit interleave (π3) have now been corrected based on their correlation with the originally correctable first information bit interleave (π1) and/or now-corrected second information bit interleave (π2), so now there are three information bit interleaves (π1, π2, and π3) that are correctable interleaves.

Now considering this diagram, if it is supposed that the 1^{st} symbol portion of the third information bit interleave (π3) having an error (indicated by “x”) straddles the 1^{st} symbol portion of the fourth ECC interleave (ECC4), and the previously 4^{th} 1^{st} symbol portion of the first information bit interleave (π1) straddles the 3^{rd} symbol portion of the fourth ECC interleave (ECC4), then the combination of the first information bit interleave (π1) and the third information bit interleave (π3) make the fourth ECC interleave (ECC4) correctable. Finally, information from each of the three information bit interleaves (π1, π2, and π3) whose errors have been corrected are employed to correct errors within the fourth information bit interleave (π4).

It can be seen that the iterative nature of the decoding presented herein, upon the error correction of some of the interleaves, the combinations made with these now-corrected interleaves may be employed to correct other of the interleaves.

In the HDD context, a whole sector is then correctable by identifying error events through the soft information values (e.g., as generated via SOVA detection) and correlating those interleaves having uncorrectable errors with interleaves having correctable errors.

When considering many of the various embodiments presented herein, it is noted that different numbers of interleaves, different sector sizes, and different ECC schemes may be alternatively employed without departing from the scope and spirit of the invention. Also, different degrees/values of ‘thresholds’ employed to determine what actually constitutes a “low reliability” bit can be adjusted as desired in a particular application. Also, iterative decoding can be employed when multiple interleaves are compromised (e.g., include errors). Generally speaking, any communication system including a communication channel that uses an error correction code with interleaves can benefit from certain aspects presented herein (e.g., including any of those communication systems depicted in FIG. 4) as well as applications employing a HDD in which the channel coupling to the storage media of the HDD is the communication channel.

In this disclosure, a performance diagram is described in the context of SFR (Sector Failure Rate) versus SNR (Signal to Noise Ratio) shown in decibels (dB). The use of SFR is particularly tailored to an HDD application in which information is written to and read from sectors of storage media within the HDD. However, within other applications (e.g., many of the various communication system types depicted in FIG. 4, among other types of communication system types), it is noted that performance diagrams are sometimes alternatively described in the context of BER (Bit Error Rate), BLER (Block Error Rate), or some other ‘error rate’ parameter versus E_{b}/Nₒ (ratio of energy per bit E_{b} to the Spectral Noise Density Nₒ). BLER is oftentimes used in the context of wireless communications where if any one bit in a block is determined to be in error, then the entire block is determined to be in error. In some other communication system application, performance may alternatively be viewed in terms of BER (Bit Error Rate) vs. E_{b}/Nₒ. This term E_{b}/Nₒ is the measure of SNR (Signal to Noise Ratio) for a digital communication system.

In this disclosure, performance diagrams taken from HDD applications are depicted, and when looking at these performance curves, the SFR may be determined for any given SNR thereby providing a relatively concise representation of the performance of the coding (e.g., decoding) approach. It is noted that the decoding presented herein can generally be applied to virtually any type of communication system, including those various communication system types depicted in FIG. 4.

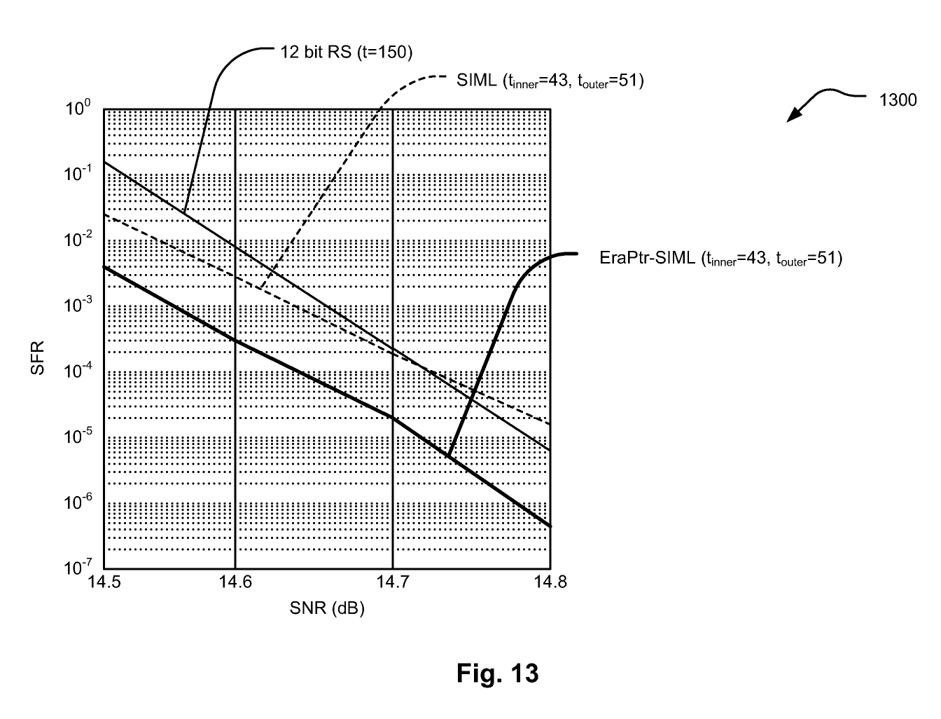

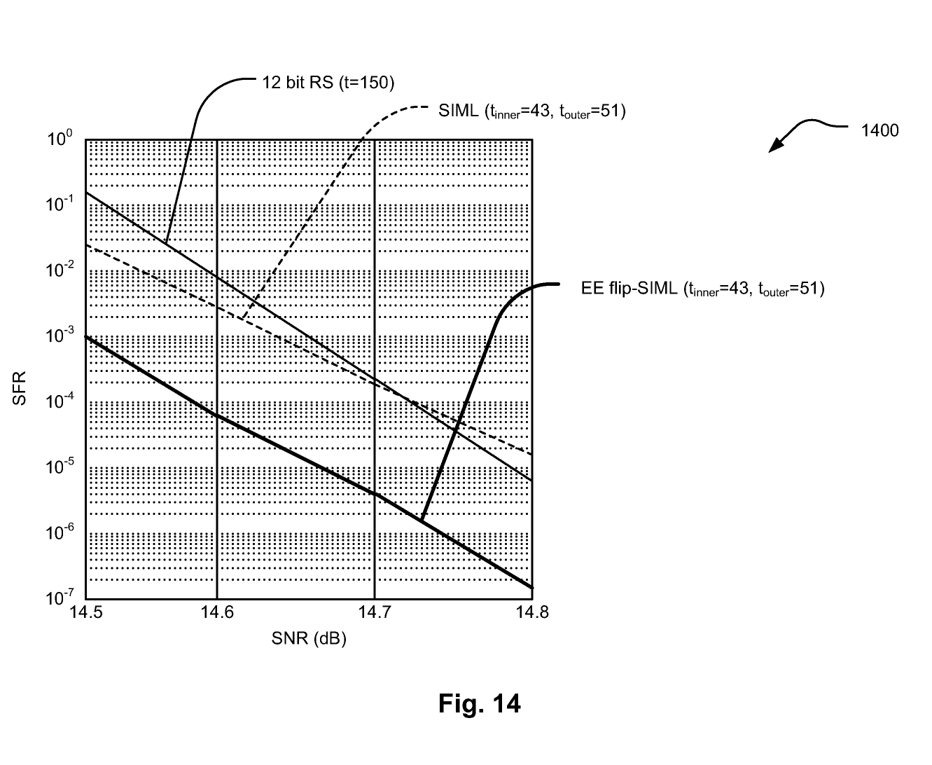

FIG. 13 and FIG. 14 illustrate embodiments of performance comparisons of various means to decode a symbol-interleaved multi-level ECC signal.

Referring to FIG. 13, a RS coded signal having 12 bit symbols and a t of 150 and a symbol-interleaved multi-level ECC signal (SIML (tᵢₙₙₑᵣ=43, tₒᵤₜₑᵣ=51) are compared with the erasure pointer decoding approach presented herein to decode a symbol-interleaved multi-level ECC signal (shown as EraPrt-SIML ((tᵢₙₙₑᵣ=43, tₒᵤₜₑᵣ=51)). As can be seen, for a given SNR, the novel approach of erasure pointer decoding as presented herein has a SFR of approximately an order of magnitude improvement (e.g., at a SNR of approximately 14.6, a SFR of approximately 3×10⁻⁴ is achieved using erasure pointer decoding).

Referring to FIG. 14, a RS coded signal having 12 bit symbols and a t of 150 and a symbol-interleaved multi-level ECC signal (SIML (tᵢₙₙₑᵣ=43, tₒᵤₜₑᵣ=51) are compared with the bit flipping decoding approach applied to an error event as presented herein to decode a symbol-interleaved multi-level ECC signal (shown as EE Flip-SIML ((tᵢₙₙₑᵣ=43, tₒᵤₜₑᵣ=51)). As can be seen, for a given SNR, the novel approach of bit flipping decoding approach applied to an error event as presented herein has a SFR of approximately slightly more than an order of magnitude improvement (e.g., at a SNR of approximately 14.6, a SFR of approximately 5×10⁻⁵ is achieved using bit flipping decoding approach applied to an error event).

Generally, it is noted that the various embodiments of decoding presented herein can employ interleaves having correctable errors to identify the boundary error events that slip into interleaves having uncorrectable errors.

In one embodiment, erasure points are employed to partner, associated, and/or correlate the boundary error events to help correct errors in the originally-characterized uncorrectable interleaves. The boundary error events in the now-corrected interleaves may then be employed to correct errors in remaining interleaves that were originally-characterized as uncorrectable interleaves. Alternatively, it is noted that errors can be corrected using bit-flipping.

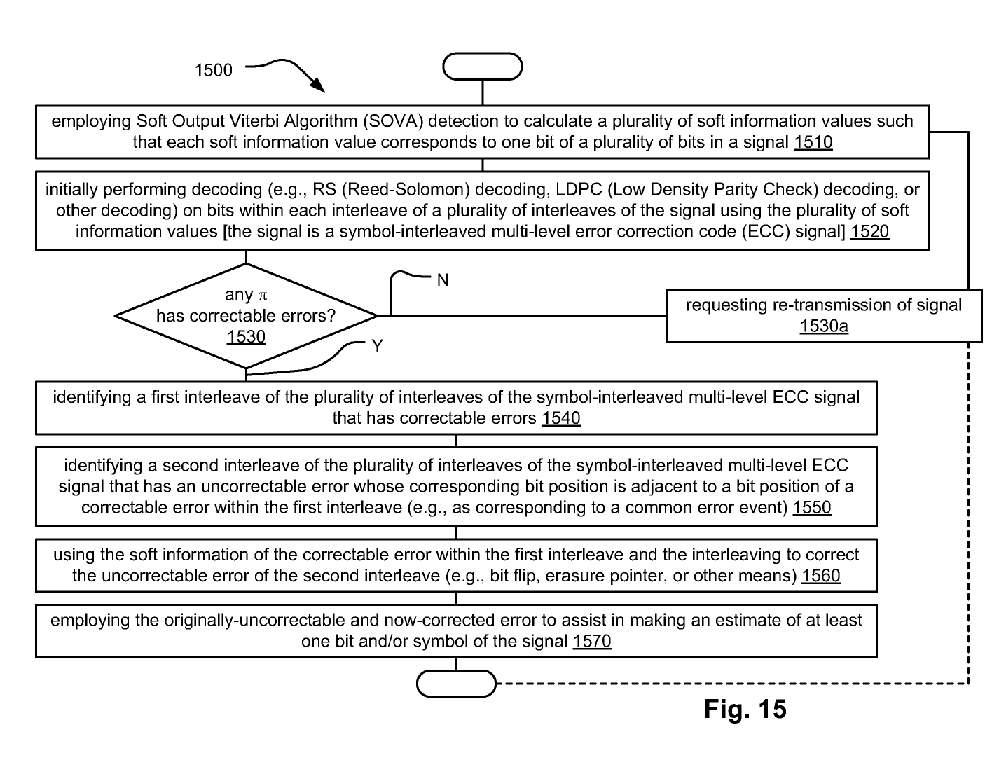

FIG. 15 illustrates an embodiment of a method 1500 for correcting an error within a signal.

The method 1500 begins by employing Soft Output Viterbi Algorithm (SOVA) detection to calculate a plurality of soft information values such that each soft information value corresponds to one bit of a plurality of bits in a signal, as shown in a block 1510.

The method 1600 continues by initially performing RS (Reed-Solomon) decoding on bits within each interleave of a plurality of interleaves of the signal using the plurality of soft information values, as shown in a block 1520. It is noted that the signal is a symbol-interleaved multi-level error correction coding (ECC) signal.

Thereafter, a decision block 1530 is employed to determine whether or not any interleave (π) has errors that are correctable. If none of the interleaves (πs) has correctable errors, then the method 1500 can operate by requesting a re-transmission of the signal, as shown in a block 1530a. The method can then begin anew or alternatively terminate at this point. Also, in an HDD context, if none of the interleaves (πs) has correctable errors, then the method 1500 can operate by performing a re-read or attempting a re-read of the signal from storage media of an HDD.

When the initial RS decoding of at least one interleave of the plurality of interleaves of the symbol-interleaved multi-level ECC signal fails (and the initial RS decoding of at least one interleave of the plurality of interleaves of the symbol-interleaved multi-level ECC signal succeeds by correcting errors therein), then the method 1500 operates by identifying a first interleave of the plurality of interleaves of the symbol-interleaved multi-level ECC signal that has correctable errors, as shown in a block 1540. The method 1500 then continues by identifying a second interleave of the plurality of interleaves of the symbol-interleaved multi-level ECC signal that has an uncorrectable error whose corresponding bit position is adjacent to a bit position of a correctable error within the first interleave (e.g., as corresponding to a common error event), as shown in a block 1550.

The method 1500 then continues by using the soft information of the correctable error within the first interleave and the interleaving to correct the uncorrectable error of the second interleave, as shown in a block 1560. This can be performed using any one of a variety of means including either identifying an erasure pointer to partner the correctable error of the first interleave and the uncorrectable error of the second interleave (e.g., that correspond to a common error event), or by performing a bit flip of the uncorrectable error within the second interleave based on its association/correlation with the correctable error of the first interleave.

The method 1500 then operates by employing the originally-uncorrectable and now-corrected error to assist in making an estimate of at least one bit and/or symbol of the signal.

The method 1500 can continue to employ the now-corrected interleaves to correct other interleaves that have been originally-characterized as having uncorrectable errors.

It is noted that the various modules (e.g., encoding modules, decoding modules, processing modules, etc.) described herein may be a single processing device or a plurality of processing devices. Such a processing device may be a microprocessor, micro-controller, digital signal processor, microcomputer, central processing unit, field programmable gate array, programmable logic device, state machine, logic circuitry, analog circuitry, digital circuitry, and/or any device that manipulates signals (analog and/or digital) based on operational instructions. The operational instructions may be stored in a memory. The memory may be a single memory device or a plurality of memory devices. Such a memory device may be a read-only memory, random access memory, volatile memory, non-volatile memory, static memory, dynamic memory, flash memory, and/or any device that stores digital information. It is also noted that when the processing module implements one or more of its functions via a state machine, analog circuitry, digital circuitry, and/or logic circuitry, the memory storing the corresponding operational instructions is embedded with the circuitry comprising the state machine, analog circuitry, digital circuitry, and/or logic circuitry. In such an embodiment, a memory stores, and a processing module coupled thereto executes, operational instructions corresponding to at least some of the steps and/or functions illustrated and/or described herein.

The present invention has also been described above with the aid of method steps illustrating the performance of specified functions and relationships thereof. The boundaries and sequence of these functional building blocks and method steps have been arbitrarily defined herein for convenience of description. Alternate boundaries and sequences can be defined so long as the specified functions and relationships are appropriately performed. Any such alternate boundaries or sequences are thus within the scope and spirit of the claimed invention.

The present invention has been described above with the aid of functional building blocks illustrating the performance of certain significant functions. The boundaries of these functional building blocks have been arbitrarily defined for convenience of description. Alternate boundaries could be defined as long as the certain significant functions are appropriately performed. Similarly, flow diagram blocks may also have been arbitrarily defined herein to illustrate certain significant functionality. To the extent used, the flow diagram block boundaries and sequence could have been defined otherwise and still perform the certain significant functionality. Such alternate definitions of both functional building blocks and flow diagram blocks and sequences are thus within the scope and spirit of the claimed invention.

One of average skill in the art will also recognize that the functional building blocks, and other illustrative blocks, modules and components herein, can be implemented as illustrated or by discrete components, application specific integrated circuits, processors executing appropriate software and the like or any combination thereof.

Moreover, although described in detail for purposes of clarity and understanding by way of the aforementioned embodiments, the present invention is not limited to such embodiments. It will be obvious to one of average skill in the art that various changes and modifications may be practiced within the spirit and scope of the invention, as limited only by the scope of the appended claims.

What is claimed is:

1. An apparatus, comprising:
a Soft Output Viterbi Algorithm (SOVA) detector implemented to calculate a plurality of soft information values such that each soft information value corresponds to one bit of a plurality of bits in a signal; and
a RS (Reed-Solomon) decoder implemented to process the plurality of soft information values to make an estimate of at least one symbol of the signal, wherein:
the signal is a symbol-interleaved error correction coding (ECC) signal;
the RS decoder initially performs decoding on bits within each interleave of a plurality of interleaves of the symbol-interleaved ECC signal;
when the initial RS decoding of at least one interleave of the plurality of interleaves of the symbol-interleaved ECC signal fails:
the RS decoder identifies a first interleave of the plurality of interleaves of the symbol-interleaved ECC signal that has a correctable error;
the RS decoder identifies a second interleave of the plurality of interleaves of the symbol-interleaved ECC signal that has an uncorrectable error whose bit position is adjacent to a bit position within the first interleave that includes the correctable error; and
to correct the uncorrectable error of the second interleave, the RS decoder either:
identifies an erasure pointer to partner the correctable error of the first interleave and the uncorrectable error of the second interleave; or
performs a bit flip of the uncorrectable error of the second interleave.

2. The apparatus of claim 1, wherein:
when the initial RS decoding of each interleave of the plurality of interleaves of the symbol-interleaved ECC signal succeeds, the RS decoder employs the initially successful RS decoding to make an estimate of a symbol within the signal.

3. The apparatus of claim 1, wherein:
when the initial RS decoding of each interleave of the plurality of interleaves of the symbol-interleaved ECC signal fails, the apparatus requests a re-transmission of the signal to the apparatus.

4. The apparatus of claim 1, wherein:
the plurality of soft information values is a plurality of log likelihood ratios (LLRs).

5. The apparatus of claim 1, wherein:
after correcting the uncorrectable error of the second interleave, the RS decoder identifies a third interleave of the plurality of interleaves of the symbol-interleaved ECC signal that has at least one additional uncorrectable error whose bit position is adjacent to the now-corrected, originally uncorrectable error of the second interleave or the correctable error of the first interleave; and
to correct the uncorrectable error of the third interleave, the RS decoder either:
identifies at least one additional erasure pointer to partner the at least one additional correctable error of the third interleave and either the now-corrected, originally uncorrectable error of the second interleave or the correctable error of the first interleave; or
performs a bit flip of the uncorrectable error of the second interleave.

6. The apparatus of claim 1, further comprising:
an LDPC (Low Density Parity Check) decoder implemented to process the plurality of soft information values to make estimate of symbols of the signal, wherein:
the LDPC decoder also initially performs decoding on bits within each interleave of the plurality of interleaves of the symbol-interleaved ECC signal;
when the initial LDPC decoding of at least one interleave of the plurality of interleaves of the symbol-interleaved ECC signal fails:
the LDPC decoder identifies the first interleave of the plurality of interleaves of the symbol-interleaved ECC signal that has the correctable error;
the LDPC decoder identifies the second interleave of the plurality of interleaves of the symbol-interleaved ECC signal that has the uncorrectable error whose bit position is adjacent to the bit position within the first interleave that includes the correctable error; and
to correct the uncorrectable error of the second interleave, the LDPC decoder either:
identifies an erasure pointer to partner the correctable error of the first interleave and the uncorrectable error of the second interleave; or
performs a bit flip of the uncorrectable error of the second interleave.

7. The apparatus of claim 1, wherein:
the symbol-interleaved ECC signal is generated from a multi-level ECC signal; and
the multi-level ECC signal includes a first information block followed by a corresponding first ECC block, a second information block followed by a corresponding second ECC block, and an extra ECC block that corresponds to the first information block, the first ECC block, the second information block, and the second ECC block.

8. The apparatus of claim 1, wherein:
the uncorrectable error of the second interleave is corrected during a first decoding iteration; and
at least one additional uncorrectable error of a third interleave of the plurality of interleaves of the symbol-interleaved ECC signal is corrected during a second decoding iteration.

9. The apparatus of claim 1, wherein:
the apparatus is implemented within an hard disk drive (HDD).

10. The apparatus of claim 1, wherein:
the apparatus is implemented within a communication device; and
the communication device is implemented within at least one of a satellite communication system, a wireless communication system, a wired communication system, and a fiber-optic communication system.

11. An apparatus, comprising:
a Soft Output Viterbi Algorithm (SOVA) detector implemented to calculate a plurality of soft information values such that each soft information value corresponds to one bit of a plurality of bits in a signal; and
a RS (Reed-Solomon) decoder implemented to process the plurality of soft information values to make estimate of symbols of the signal, wherein:
the signal is a symbol-interleaved error correction coding (ECC) signal;
the RS decoder initially performs decoding on bits within each interleave of a plurality of interleaves of the symbol-interleaved ECC signal;
when the initial RS decoding of at least one interleave of the plurality of interleaves of the symbol-interleaved ECC signal fails:
the RS decoder identifies a first interleave of the plurality of interleaves of the symbol-interleaved ECC signal that has a correctable error;
the RS decoder identifies a second interleave of the plurality of interleaves of the symbol-interleaved ECC signal that has an uncorrectable error whose bit position is adjacent to a bit position within the first interleave that includes the correctable error; and
to correct the uncorrectable error of the second interleave, the RS decoder either:
identifies an erasure pointer to partner the correctable error of the first interleave and the uncorrectable error of the second interleave; or
performs a bit flip of the uncorrectable error of the second interleave;
when the initial RS decoding of each interleave of the plurality of interleaves of the symbol-interleaved ECC signal succeeds, the RS decoder employs the initially successful RS decoding to make an estimate of a symbol within the signal; and
when the initial RS decoding of each interleave of the plurality of interleaves of the symbol-interleaved ECC signal fails, the apparatus requests a re-transmission of the signal to the apparatus.

12. The apparatus of claim 11, wherein:
after correcting the uncorrectable error of the second interleave, the RS decoder identifies a third interleave of the plurality of interleaves of the symbol-interleaved ECC signal that has at least one additional uncorrectable error whose bit position is adjacent to the now-corrected, originally uncorrectable error of the second interleave or the correctable error of the first interleave; and
to correct the uncorrectable error of the third interleave, the RS decoder either:
identifies at least one additional erasure pointer to partner the at least one additional correctable error of the third interleave and either the now-corrected, originally uncorrectable error of the second interleave or the correctable error of the first interleave; or
performs a bit flip of the uncorrectable error of the second interleave.

13. The apparatus of claim 11, wherein:
the uncorrectable error of the second interleave is corrected during a first decoding iteration; and
at least one additional uncorrectable error of a third interleave of the plurality of interleaves of the symbol-interleaved ECC signal is corrected during a second decoding iteration.

14. The apparatus of claim 11, wherein:
the apparatus is implemented within an hard disk drive (HDD).

15. The apparatus of claim 11, wherein:
the apparatus is implemented within a communication device; and
the communication device is implemented within at least one of a satellite communication system, a wireless communication system, a wired communication system, and a fiber-optic communication system.

16. A method for correcting an error within a signal, the method comprising:
employing Soft Output Viterbi Algorithm (SOVA) detection to calculate a plurality of soft information values such that each soft information value corresponds to one bit of a plurality of bits in a signal;
initially performing RS (Reed-Solomon) decoding on bits within each interleave of a plurality of interleaves of the signal using the plurality of soft information values, wherein the signal is a symbol-interleaved error correction coding (ECC) signal;
when the initial RS decoding of at least one interleave of the plurality of interleaves of the symbol-interleaved ECC signal fails:
identifying a first interleave of the plurality of interleaves of the symbol-interleaved ECC signal that has a correctable error;
identifying a second interleave of the plurality of interleaves of the symbol-interleaved ECC signal that has an uncorrectable error whose bit position is adjacent to a bit position within the first interleave that includes the correctable error; and
correcting the uncorrectable error of the second interleave by either:
identifying an erasure pointer to partner the correctable error of the first interleave and the uncorrectable error of the second interleave; or
performing a bit flip of the uncorrectable error of the second interleave; and
employing the originally-uncorrectable and now-corrected error to make an estimate of at least one symbol of the signal.

17. The method of claim 16, further comprising:
when the initial RS decoding of each interleave of the plurality of interleaves of the symbol-interleaved ECC signal succeeds, employing the initially successful RS decoding to make an estimate of a symbol within the signal; and
when the initial RS decoding of each interleave of the plurality of interleaves of the symbol-interleaved ECC signal fails, requesting a re-transmission of the signal from a sending communication device that originally sent the signal.

18. The method of claim 16, wherein:
the symbol-interleaved ECC signal is generated from a multi-level ECC signal; and
the multi-level ECC signal includes a first information block followed by a corresponding first ECC block, a second information block followed by a corresponding second ECC block, and an extra ECC block that corresponds to the first information block, the first ECC block, the second information block, and the second ECC block.

19. The method of claim 16, wherein:
the method is performed within a hard disk drive (HDD).

20. The method of claim 16, wherein:
the method is performed within a communication device; and
the communication device is implemented within at least one of a satellite communication system, a wireless communication system, a wired communication system, and a fiber-optic communication system.
